(19) United States
(12) Patent Application Publication
(10) Pub. No.: US 2024/0072017 A1
(43) Pub. Date: Feb. 29, 2024

(54) PIXEL UNIT WITH RGB LIGHT-EMITTING DIODES

(71) Applicant: Lextar Electronics Corporation, Hsinchu City (TW)

(72) Inventors: Ching-Yi CHEN, Hsinchu City (TW); Wei-An CHEN, Hsinchu City (TW)

(21) Appl. No.: 18/450,605

(22) Filed: Aug. 16, 2023

(30) Foreign Application Priority Data
Aug. 31, 2022 (TW) 111132824

(51) Int. Cl. H01L 25/075

(52) U.S. Cl. CPC H01L 25/0753

(57) ABSTRACT

A pixel unit includes a red LED chip, a green LED chip, and a blue LED chip. Each of these chips has an optical density concentration zone and a reference line passing through the geometric center of the top-view shape of the chip. The optical density concentration zone of each of these chips is deviated to one side of the respective reference line of the chip. The reference lines of the chips are parallel to each other. The optical density concentration zones of the chips are all deviated to the same side of the respective reference line.

### CROSS REFERENCE TO RELATED APPLICATIONS

This application claims the benefit of Taiwan Application No. 111132824, filed on Aug. 31, 2022, and the content of the entirety of which is incorporated by reference herein.

### BACKGROUND OF THE DISCLOSURE

### Field of the Invention

The present disclosure relates to a pixel unit in an electronic device, and, in particular, to a pixel unit with RGB light-emitting diodes.

### Description of the Related Art

In recent years, light-emitting diodes (LEDs) have been widely used in various lighting components and display components due to their advantages, which include high brightness, small size, and energy savings. In existing LED displays, three primary color LED chips of red, green and blue are directly used in the pixel unit in order to achieve a better display quality.

### BRIEF SUMMARY OF THE DISCLOSURE

An embodiment of the present disclosure provides a pixel unit including a red light-emitting diode (LED) chip, a green LED chip, and a blue LED chip. The red LED chip has an optical density concentration zone and a reference line passing through a geometric center of the top-view shape of the red LED chip. The optical density concentration zone of the red LED chip is deviated to one side of the reference line of the red LED chip. The green LED chip has an optical density concentration zone and a reference line passing through a geometric center of the top-view shape of the green LED chip. The optical density concentration zone of the green LED chip is deviated to one side of the reference line of the green LED chip. The blue LED chip has an optical density concentration zone and a reference line passing through a geometric center of the top-view shape of the blue LED chip. The optical density concentration zone of the blue LED chip is deviated to one side of the reference line of the blue LED chip. The reference line of the red LED chip, the reference line of the green LED chip, and the reference line of the blue LED chip are parallel to each other. The optical density concentration zone of the red LED chip, the optical density concentration zone of the green LED chip, and the optical density concentration zone of the blue LED chip are all deviated to the same side of the respective reference line.

An embodiment of the present disclosure provides a pixel unit including a red LED chip, a green LED chip, and a blue LED chip. Each of the red LED chip, the green LED chip, and the blue LED chip has a reference line passing through a geometric center of the top-view shape of the respective chip, and the reference lines of the red LED chip, the green LED chip and the blue LED chip are parallel to each other. Each of the red LED chip, the green LED chip, and the blue LED chip has different average brightness on both sides of the reference line, and the side with higher average brightness of the red LED chip, the green LED chip and the blue LED chip are the same side of the respective reference line.

An embodiment of the present disclosure provides a pixel unit including a red LED chip, a green LED chip, and a blue LED chip. The respective light patterns of the red LED chip, the green LED chip, and the blue LED chip are asymmetric with respect to the 0-degree viewing angle. The respective light patterns of the red LED chip, the green LED chip, and the blue LED chip are deviated to the same side with respect to the 0-degree viewing angle.

### BRIEF DESCRIPTION OF THE DRAWINGS

The disclosure can be more fully understood by reading the subsequent detailed description with references made to the accompanying figures. It should be understood that the figures are not drawn to scale in accordance with standard practice in the industry. In fact, it is allowed to arbitrarily enlarge or reduce the size of components for clear illustration. This means that many special details, relationships and methods are disclosed to provide a complete understanding of the disclosure.

FIG. 1A is a schematic diagram of a display component in accordance with some embodiments of the present disclosure.

FIG. 1B is a cross-sectional structure diagram of FIG. 1A along a cutting line I-I in accordance with some embodiments of the present disclosure.

FIG. 2A is a schematic diagram of a display component in accordance with some embodiments of the present disclosure.

FIG. 2B is a cross-sectional structure diagram of FIG. 2A along a cutting line II-II in accordance with some embodiments of the present disclosure.

FIG. 3A is a schematic diagram of a display component in accordance with some embodiments of the present disclosure.

FIG. 3B is a cross-sectional structure diagram of FIG. 3A along a cutting line III-III in accordance with some embodiments of the present disclosure.

FIG. 4A is a schematic diagram of a pixel unit in accordance with some embodiments of the present disclosure.

FIG. 4B is a schematic diagram of a pixel unit in accordance with some embodiments of the present disclosure.

FIG. 5 is a graph of a light pattern and a color difference of a pixel unit in accordance with some embodiments of the present disclosure.

### DETAILED DESCRIPTION OF THE DISCLOSURE

In order to make the above purposes, features, and advantages of some embodiments of the present disclosure more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” and/or “include” used in the present disclosure are used to indicate the existence of specific technical features, values, method steps, operations, units and/or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

It should be noted that the technical features in different embodiments described in the following can be replaced, recombined, or mixed with one another to constitute another embodiment without departing from the spirit of the present disclosure.

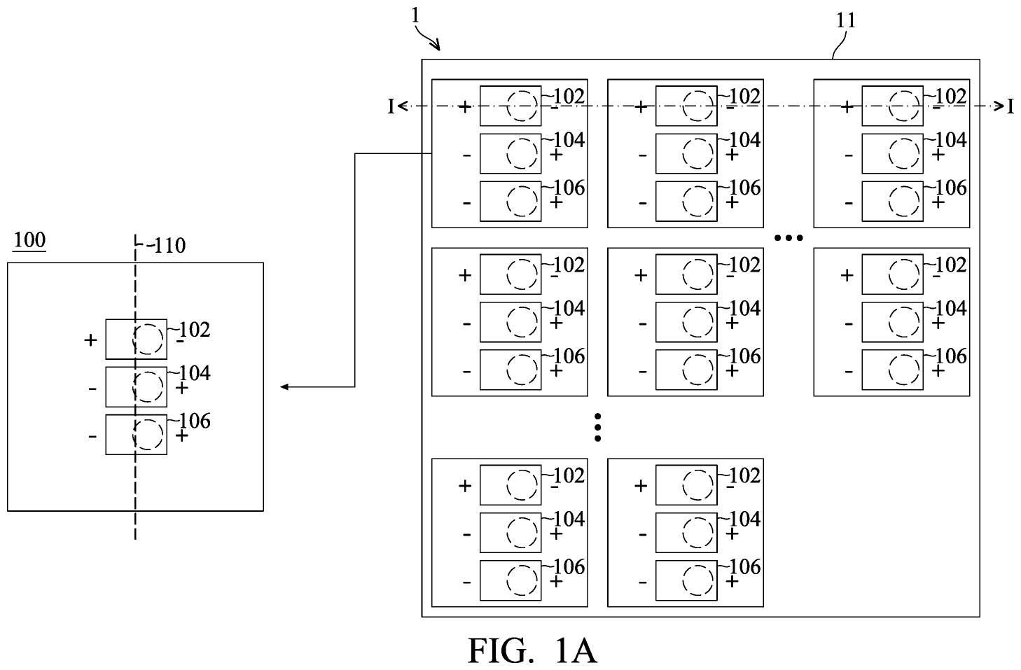

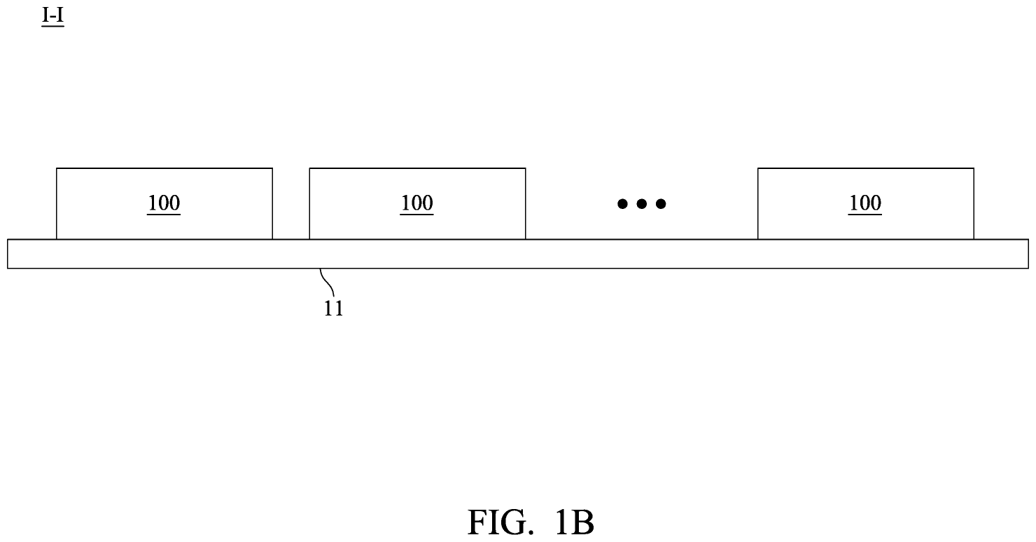

FIG. 1A is a schematic diagram of a display component 1 in accordance with some embodiments of the present disclosure. As shown in FIG. 1A, the display component 1 includes a plurality of pixel units 100. The pixel units 100 are disposed on a display substrate 11. The pixel unit 100 includes a red LED chip 102, a green LED chip 104, and a blue LED chip 106. In some embodiments, the red LED chip 102 includes a reference line 110 passing through the geometric center of the top-view shape of the red LED chip 102. The green LED chip 104 includes the reference line 110 passing through the geometric center of the top-view shape of the green LED chip 104. The blue LED chip 106 includes the reference line 110 passing through the geometric center of the top-view shape of the blue LED chip 106. In some embodiments, the reference line passing through the geometric center of the top-view shape of the chip divides the top-view shape of the chip into two symmetric regions under the top-view. For example, the red LED chip 102 is divided into two symmetric regions by the reference line 110: the left side of the reference line 110 and the right side of the reference line 110. In some embodiments, the top view shapes of the red LED chip 102, the green LED chip 104, and the blue LED chip 106 are rectangles. The reference line 110 passes through the geometric center of each chip under the top-view along the short side of the rectangle. In some embodiments, the red LED chip 102, the green LED chip 104, and the blue LED chip 106 are disposed in such a manner that their long sides are parallel to each other. In some embodiments of FIG. 1A, the red LED chip 102, the green LED chip 104, and the blue LED chip 106 are all disposed along the direction of the reference line 110, but the present disclosure does not limit the arrangement order among the red LED chip 102, the green LED chip 104, and the blue LED chip 106.

In some embodiments, the red LED chip 102 has an optical density concentration zone deviated to one side of the reference line 110. The green LED chip 104 has an optical density concentration zone deviated to one side of the reference line 110. The blue LED chip 106 has an optical density concentration zone deviated to one side of the reference line 110. The optical density concentration zone is a place where the luminous brightness is concentrated. For example, in some embodiments, the optical density concentration zone of the red LED chip 102 is deviated to the right side of the reference line 110. The optical density concentration zone of the green LED chip 104 is deviated to the right side of the reference line 110. The optical density concentration zone of the blue LED chip 106 is deviated to the right side of the reference line 110. That is, the optical density concentration zone of each of the red LED chip 102, the green LED chip 104, and the blue LED chip 106 is deviated to the same side of the reference line 110. In other words, in some embodiments, the circle in each chip represents the optical density concentration zone of each chip. In some embodiments, the two symmetrical regions divide by the reference line of the chip have different average brightness. That is, the two side regions of the reference line of the chip have different average brightness from each other. For example, the average brightness of the respective regions on both sides of the reference line 110 of each of the red LED chip 102, the green LED chip 104, and the blue LED chip 106 are different from each other, and the respective regions with the higher average brightness of the three are all located on the same side of the reference line 110. In some embodiments of FIG. 1A, the average brightness of the respective regions on both sides of the reference line 110 of each of the red LED chip 102, the green LED chip 104, and the blue LED chip 106 are different from each other, and the respective regions with the higher average brightness of the three chips are all located on the right side of the reference line 110.

In some embodiments, each of the red LED chip 102, the green LED chip 104, and the blue LED chip 106 includes a positive electrode (+) and a negative electrode (−), and the positive electrode (+) and the negative electrode (−) are located on different sides of the respective reference line 110. For example, the positive electrode (+) of the red LED chip 102 is disposed on the left side of the reference line 110 and the negative electrode (−) of the red LED chip 102 is disposed on the right side of the reference line 110. The positive electrode (+) of the green LED chip 104 is disposed on the right side of the reference line 110 and the negative electrode (−) of the green LED chip 104 is disposed on the left side of the reference line 110. The positive electrode (+) of the blue LED chip 106 is disposed on the right side of the reference line 110 and the negative electrode (−) of the blue LED chip 106 is disposed on the left side of the reference line 110.

In some embodiments, the optical density concentration zone of one of the chips, such as the red LED chip 102, is closer to its positive electrode (+). The optical density concentration zone of the other chips, such as the green LED chip 104 and the blue LED chip 106, are closer to its negative electrode (−). In other words, the optical density concentration zone of one of the chips is deviated to the side of its positive electrode (+) and the optical density concentration zone of the other chips are deviated to the side of its negative electrode (−). For example, in some embodiments of FIG. 1A, the optical density concentration zone of the red LED chip 102 is deviated to the side of the negative electrode (−) (e.g., the right side of the reference line 110) of the red LED chip 102. The optical density concentration zones of the green LED chip 104 and the blue LED chip 106 are deviated to the side of the positive electrode (e.g., the right side of the reference line 110) of the respective chips.

In some embodiments, for one of the red LED chip 102, the green LED chip 104, and the blue LED chip 106, the positive electrode (+) of the chip itself and the region with the higher average brightness of the chip itself are located on the same side of the reference line 110. For the other one or two of the red LED chip 102, the green LED chip 104, and the blue LED chip 106, the negative electrode (−) of the chip itself and the region with the higher average brightness of the chip itself are located on the same side of the reference line 110. For example, in some embodiments, the negative electrode (−) of the red LED chip 102 and the region with the higher average brightness of the red LED chip 102 are located on the same side of the reference line 110 (e.g., the right side of the reference line 110). The positive electrode (+) of the green LED chip 104 and the region with the higher average brightness of the green LED chip 104 are located on the same side of the reference line 110 (e.g., the right side of the reference line 110). The positive electrode (+) of the blue LED chip 106 and the region with the higher average brightness of the blue LED chip 106 are located on the same side of the reference line 110 (e.g., the right side of the reference line 110).

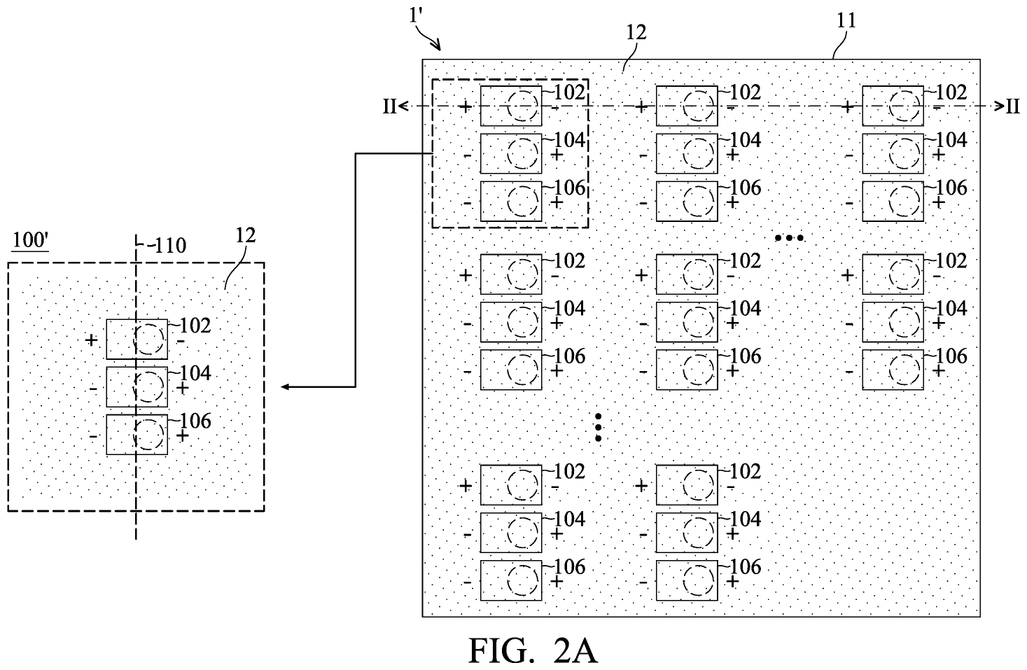

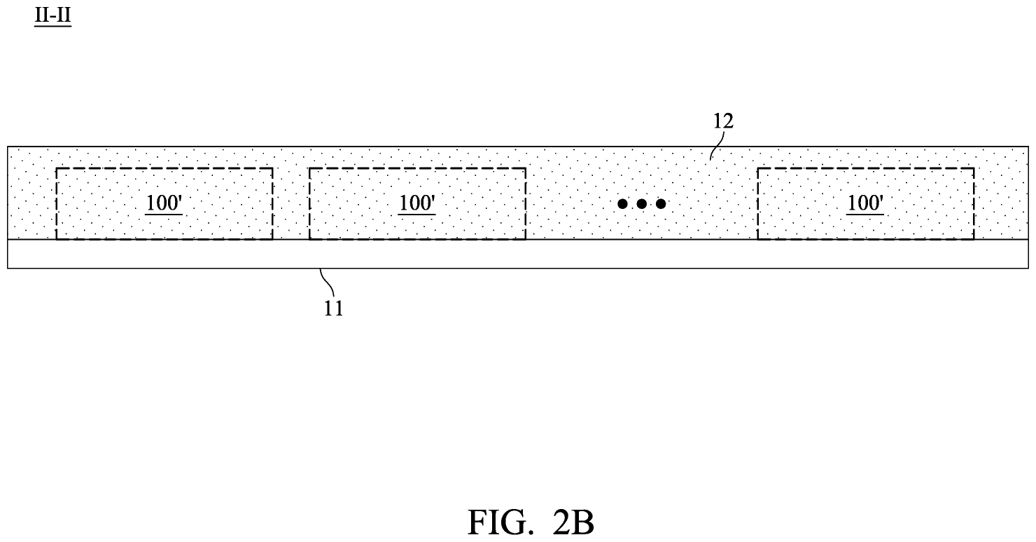

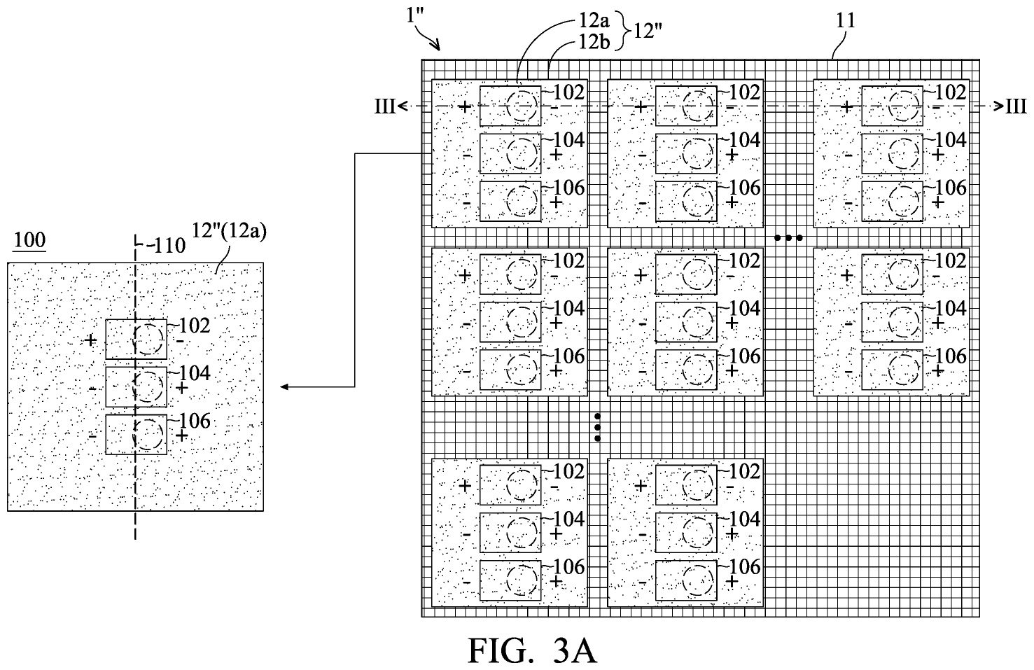

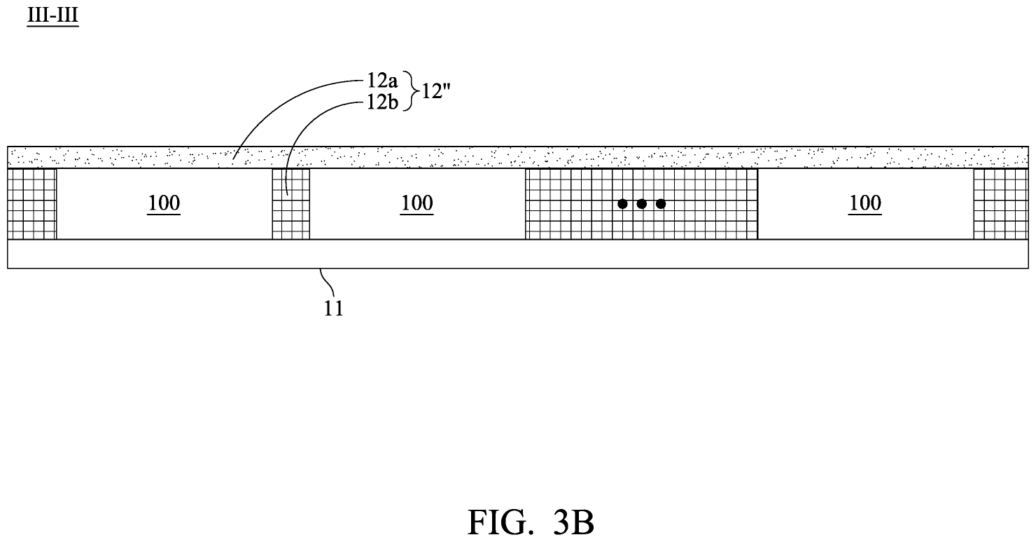

In some embodiments, the display component may be in the form of variant types, such as package on board (POB), chip on board (COB), or glue on board (GOB). FIG. 1A is a schematic diagram of a POB display component 1 in accordance with some embodiments of the present disclosure. FIG. 1B is a cross-sectional structure diagram of FIG. 1A along a cutting line I-I in accordance with some embodiments of the present disclosure. As shown in FIG. 1A and FIG. 1B, the plurality of pixel units 100 disposed on the display substrate 11 are packages separated from each other. Each package includes the red LED chip 102, the green LED chip 104, and the blue LED chip 106. The aforementioned LED chips are all sealed in the corresponding package to protect the LED chips from the external environment. FIG. 2A is a schematic diagram of a COB display component 1′ in accordance with some embodiments of the present disclosure. FIG. 2B is a cross-sectional structure diagram of FIG. 2A along a cutting line II-II in accordance with some embodiments of the present disclosure. As shown in FIG. 2A and FIG. 2B, the display component 1′ includes a plurality of pixel units 100′ and a colloid 12. The pixel unit 100′ includes the red LED chip 102, the green LED chip 104, and the blue LED chip 106 directly disposed on the display substrate 11. The plurality of pixel units 100′ are embedded in the colloid 12, and the colloid 12 may be penetrated by the light emitted by the pixel unit 100′ so as to improve the light uniformity of the display component 1′. FIG. 3A is a schematic diagram of a GOB display component 1″ in accordance with some embodiments of the present disclosure. FIG. 3B is a cross-sectional structure diagram of FIG. 3A along a cutting line III-III in accordance with some embodiments of the present disclosure. As shown in FIG. 3A and FIG. 3B, the display component 1″ includes a plurality of pixel units 100 and a colloid 12″. The details of the pixel units 100 are the same as those in FIG. 1A, and are not repeated herein. The plurality of pixel units 100 are embedded in the colloid 12″, the colloid 12″ includes an upper portion 12a and a lower portion 12b. The upper portion 12a covers the pixel units 100, and the lower portion 12b surrounds the pixel units 100 and is covered by the upper portion 12a. The light emitted by the pixel units 100 can penetrate the upper portion 12a but cannot penetrate the lower portion 12b, so that the contrast between the pixel units 100 can be increased.

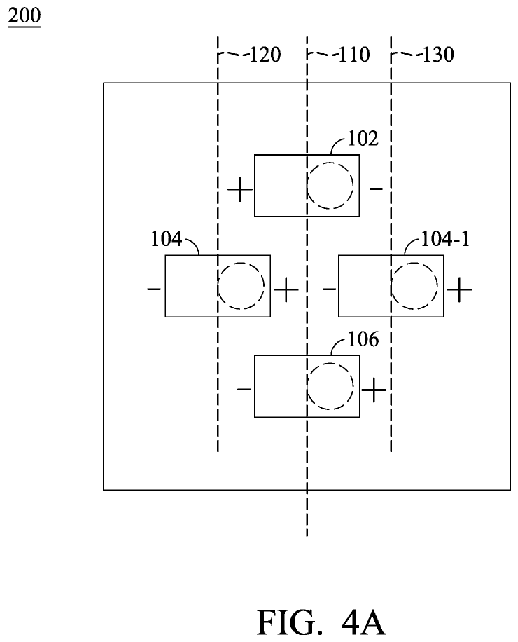

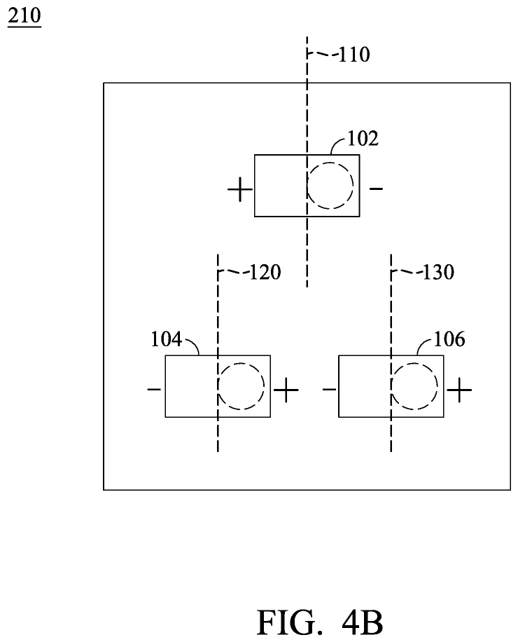

FIG. 4A is a schematic diagram of a pixel unit 200 in accordance with some embodiments of the present disclosure. As shown in FIG. 4A, the pixel unit 200 includes the red LED chip 102, the green LED chip 104, a green LED chip 104-1, and the blue LED chip 106. In some embodiments, the red LED chip 102 includes the reference line 110 passing through the geometric center of the top-view shape of the red LED chip 102. The blue LED chip 106 includes the reference line 110 passing through the geometric center of the top-view shape of the blue LED chip 106. The green LED chip 104 includes a reference line 120 passing through the geometric center of the top-view shape of the green LED chip 104. The green LED chip 104-1 includes a reference line 130 passing through the geometric center of the top-view shape of the green LED chip 104-1. In some embodiments, the reference line 110, the reference line 120, and the reference line 130 are parallel to each other. In some embodiments, the reference line 110, the reference line 120, and the reference line 130 respectively divides the top-view shape of the corresponding chip into two symmetrical regions. In some embodiments, the top view shapes of the red LED chip 102, the green LED chip 104, the green LED chip 104-1, and the blue LED chip 106 are rectangles. The reference line 110, the reference line 120, and the reference line 130 pass through the respective geometric centers of the top-view shape of the chip along the short side of the rectangle. In some embodiments, the red LED chip 102, the green LED chip 104, the green LED chip 104-1, and the blue LED chip 106 are disposed in such a manner that the long sides of the rectangles are parallel to each other. In some embodiments of FIG. 4A, the red chip 102, the green LED chip 104, the green LED chip 104-1, and the blue LED chip 106 are disposed in a diamond shape in the pixel unit 200.

In some embodiments, the red LED chip 102 and the blue LED chip 106 respectively have an optical density concentration zone deviated to one side of the reference line 110. For example, in some embodiments of FIG. 4A, the optical density concentration zone of the red LED chip 102 is deviated to the right side of the reference line 110. The optical density concentration zone of the blue LED chip 106 is deviated to the right side of the reference line 110. The green LED chip 104 has an optical density concentration zone deviated to one side of the reference line 120. The green LED chip 104-1 has an optical density concentration zone deviated to one side of the reference line 130. For example, in some embodiments of FIG. 4A, the optical density concentration zone of the green LED chip 104 is deviated to the right side of the reference line 120. The optical density concentration zone of the green LED chip 104-1 is deviated to the right side of the reference line 130. In other words, in some embodiments of FIG. 4A, the circle in each chip represents the optical density concentration zone of each chip. In some embodiments, the average brightness of the regions on the two sides of the reference line 110 of the red LED chip 102 are different, and the average brightness of the regions on the two sides of the reference 110 of the blue LED chip 106 are different. The regions with higher average brightness of the red LED chip 102 and the blue LED chip 106 are located on the same side of the reference line 110. For example, in some embodiments of FIG. 4A, the regions with higher average brightness of the red LED chip 102 and the blue LED chip 106 are located on the right side of the reference line 110.

In some embodiments, the average brightness of the regions on the two sides of the reference line 120 of the green LED chip 104 are different. The average brightness of the regions on the two side of the reference line 130 of the green LED chip 104-1 are different. The reference line 120 and the reference line 130 are parallel to each other. The region with higher average brightness of the reference line 120 of the green chip 104 and that of the reference line 130 of the green chip 104-1 are on the same side. For example, in some embodiments of FIG. 4A, the region with higher average brightness of the green LED chip 104 is on the right side of the reference line 120. The region with higher average brightness of the green LED chip 104-1 is on the right side of the reference line 130.

In some embodiments, each of the red LED chip 102, the green LED chip 104, the green LED chip 104-1, and the blue LED chip 106 includes a positive electrode (+) and a negative electrode (−). The positive electrode (+) and the negative electrode (−) are respectively located on different sides of the respective reference lines. For example, the positive electrode (+) of the red LED chip 102 is disposed on the left side of the reference line 110. The negative electrode (−) of the red LED chip 102 is disposed on the right side of the reference line 110. The positive electrode (+) of the blue LED chip 106 is disposed on the right side of the reference line 110. The negative electrode (−) of the blue LED chip 106 is disposed on the left side of the reference line 110. The positive electrode (+) of the green LED chip 104 is disposed on the right side of the reference line 120. The negative electrode (−) of the green LED chip 104 is disposed on the left side of the reference line 120. The positive electrode (+) of the green LED chip 104-1 is disposed on the right side of the reference line 130. The negative electrode (−) of the green LED chip 104-1 is disposed on the left side of the reference line 130.

In some embodiments, the optical density concentration zone of one of the chips, such as the red LED chip 102, is closer to the positive electrode (+) of the respective chip. The optical density concentration zone of the other chips, such as the green LED chip 104, the green LED chip 104-1, and the blue LED chip 106, are closer to the negative electrode (−) of the respective chip. In other words, the optical density concentration zone of one of the chips is deviated to the side of the positive electrode (+) of the chip and the optical density concentration zone of the other chips are deviated to the side of the negative electrode (−) of the chip. For example, in some embodiments of FIG. 4A, the optical density concentration zone of the red LED chip 102 is deviated to the side of the negative electrode (−) of the red LED chip 102 (that is, the right side of the reference line 110). The optical density concentration zone of the blue LED chip 106 is deviated to the side of the positive electrode (+) of the blue LED chip 106 (that is, the right side of the reference line 110). The optical density concentration zone of the green LED chip 104 is deviated to the side of the positive electrode (+) of the green LED chip 104 (that is, the right side of the reference line 120). The optical density concentration zone of the green LED chip 104-1 is deviated to the side of the positive electrode (+) of the green LED chip 104-1 (that is, the right side of the reference line 130).

In some embodiments, for one of the chips, i.e. the red LED chip 102, the green LED chip 104, the green LED chip 104-1, and the blue LED chip 106, the positive electrode (+) of the chip itself and the region with the higher average brightness of the chip itself are located on the same side of the respective reference line. For the other one or two or three of the chips, i.e. the red LED chip 102, the green LED chip 104, the green LED chip 104-1, and the blue LED chip 106, the negative electrode (−) of the chip itself and the region with the higher average brightness of the chip itself are located on the same side of the respective reference line. For example, in some embodiments of FIG. 4A, the negative electrode (−) of the red LED chip 102 and the region with the higher average brightness of the red LED chip 102 are located on the same side of the reference line 110 (that is, the right side of the reference line 110). The positive electrode (+) of the green LED chip 104 and the region with the higher average brightness of the green LED chip 104 are located on the same side of the reference line 120 (that is, the right side of the reference line 120). The positive electrode (+) of the green LED chip 104-1 and the region with the higher brightness of the green LED chip 104-1 are located on the same side of the reference line 130 (that is, the right side of the reference line 130). The positive electrode (+) of the blue LED chip 106 and the region with the higher average luminance value of the blue LED chip 106 are located on the same side of the reference line 110 (that is, the right side of the reference line 110).

FIG. 4B is a schematic diagram of a pixel unit 210 in accordance with some embodiments of the present disclosure. As shown in FIG. 4B, the pixel unit 210 includes the red LED chip 102, the green LED chip 104, and the blue LED chip 106. In some embodiments, the top-view shapes of the red LED chip 102, the green LED chip 104, and the blue LED chip 106 are all rectangular. In some embodiments, the red LED chip 102, the green LED chip 104, and the blue LED chip 106 are disposed in such a manner that their long sides are parallel to each other. In some embodiments, the red LED chip 102 includes a reference line 110 passing through the geometric center of the top-view shape of the red LED chip 102. The green LED chip 104 includes a reference line 120 passing through the geometric center of the top-view shape of the green LED chip 104. The blue LED chip 106 includes a reference line 130 passing through the geometric center of the top-view shape of the blue LED chip 106. In some embodiments, the reference line 110, the reference line 120, and the reference line 130 are parallel to each other. In some embodiments, the reference line 110, the reference line 120, and the reference line 130 respectively divide the top-view shape of the corresponding chip into two symmetrical regions. In some embodiments of FIG. 4B, the red LED chip 102, the green LED chip 104, and the blue LED chip 106 are disposed in a triangle in the pixel unit 210.

In some embodiments, the red LED chip 102 has an optical density concentration zone deviated to one side of the reference line 110. For example, in some embodiments of FIG. 4B, the optical density concentration zone of the red LED chip 102 is deviated to the right side of the reference line 110. The green LED chip 104 has an optical density concentration zone deviated to one side of the reference line 120. For example, in some embodiments of FIG. 4B, the optical density concentration zone of the green LED chip 104 is deviated to the right side of the reference line 120. The blue LED chip 106 has an optical density concentration zone deviated to one side of the reference line 130. For example, in some embodiments of FIG. 4B, the optical density concentration zone of the blue LED chip 106 is deviated to the right side of the reference line 130. In other words, in some embodiments of FIG. 4B, the circle in each chip represents the optical density concentration zone of each chip. In some embodiments, the reference line 110, the reference line 120, and the reference line 130 are parallel to each other, and the respective optical density concentration zones of the red LED chip 102, the green LED chip 104 and the blue LED chip 106 are on the same side of the respective reference lines.

In some embodiments, the average brightness of the red LED chip 102 on the two sides of the reference line 110 are different. For example, in some embodiments of FIG. 4B, the region of the red LED chip 102 with the higher average brightness is located on the right side of the reference line 110. The average brightness of the green LED chip 104 on the two sides of the reference line 120 are different. For example, in some embodiments of FIG. 4B, the region of the green LED chip 104 with the higher average brightness is located on the right side of the reference line 120. The average brightness of the blue LED chip 106 on the two sides of the reference line 130 are different. For example, in some embodiments of FIG. 4B, the region of the blue LED chip 106 with the higher average brightness is located on the right side of the reference line 130. In some embodiments, the reference line 110, the reference line 120, and the reference line 130 are parallel to each other, and the regions with the higher average brightness of the respective chips are on the same side of the respective reference line.

Similarly, in some embodiments of FIG. 4B, each of the red LED chip 102, the green LED chip 104, and the blue LED chip 106 includes a positive electrode (+) and a negative electrode (−). The positive electrode (+) and the negative electrode (−) are located on different sides of the respective reference lines. For example, the positive electrode (+) of the red LED chip 102 is disposed on the left side of the reference line 110. The negative electrode (−) of the red LED chip 102 is disposed on the right side of the reference line 110. The positive electrode (+) of the green LED chip 104 is disposed on the right side of the reference line 120. The negative electrode (−) of the green LED chip 104 is disposed on the left side of the reference line 120. The positive electrode (+) of the blue LED chip 106 is disposed on the right side of the reference line 130. The negative electrode (−) of the blue LED chip 106 is disposed on the left side of the reference line 130.

In some embodiments, the optical density concentration zone of one of the chips, such as the red LED chip 102, is closer to the positive electrode (+) of the respective chip. The optical density concentration zone of the other chips, such as the green LED chip 104 and the blue LED chip 106, are closer to the negative electrode (−) of the respective chip. In other words, the optical density concentration zone of one of the chips is deviated to the side of the positive electrode (+) of the respective chip and the optical density concentration zone of the other chips are deviated to the side of the negative electrode (−) of the respective chip. For example, the optical density concentration zone of the red LED chip 102 is deviated to the side of the negative electrode (−) of the red LED chip 102 (that is, the right side of the reference line 110). The optical density concentration zone of the green LED chip 104 is deviated to the side of the positive electrode (+) of the green LED chip 104 (that is, the right side of the reference line 120). The optical density concentration zone of the blue LED chip 106 is deviated to the side of the positive electrode (+) of the blue LED chip 106 (that is, the right side of the reference line 130).

In some embodiments, for one of the chips, i.e. the red LED chip 102, the green LED chip 104, and the blue LED chip 106, the positive electrode (+) of the chip itself and the region with the higher average brightness of the chip itself are located on the same side of the respective reference line. For the other one or two of the chips, i.e. the red LED chip 102, the green LED chip 104, and the blue LED chip 106, the negative electrode (−) of the chip itself and the region with the higher average brightness of the chip itself are located on the same side of the respective reference line. For example, the negative electrode (−) of the red LED chip 102 and the region with the higher average brightness of the red LED chip 102 are located on the same side of the reference line 110 (the right side of the reference line 110). The positive electrode (+) of the green LED chip 104 and the region with the higher average brightness of the green LED chip 104 are located on the same side of the reference line 120 (the right side of the reference line 120). The positive electrode (+) of the blue LED chip 106 and the region with the higher average brightness of the blue LED chip 106 are located on the same side of the reference line 130 (the right side of the reference line 130).

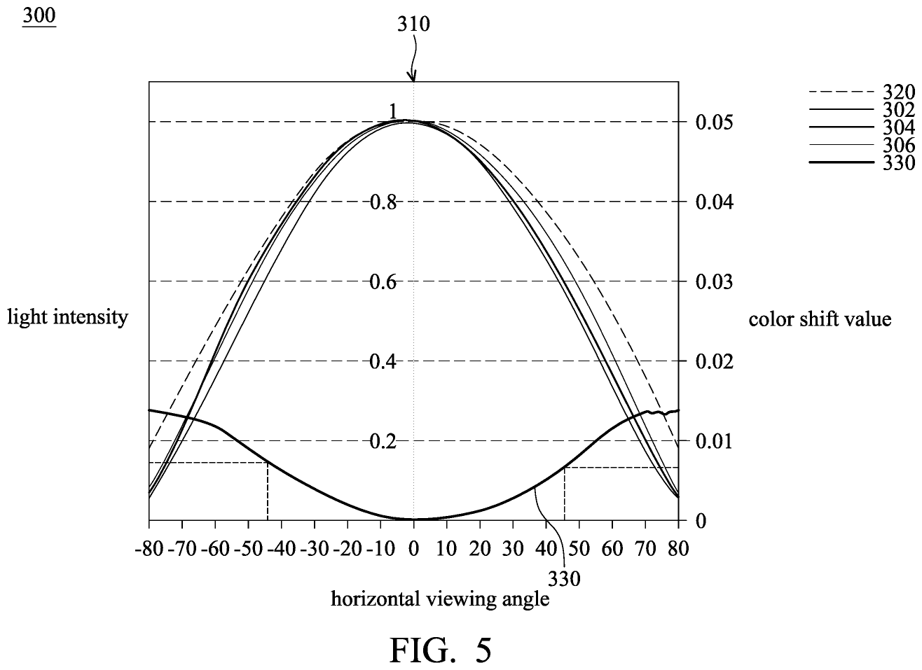

FIG. 5 is a graph of a light pattern and a color difference of a pixel unit 100 in FIG. 1A in accordance with some embodiments of the present disclosure. The horizontal axis coordinates of the graph 300 in FIG. 5 represent the viewing angle in the horizontal direction, that is, the direction of the common viewing angles for general users when viewing a display. The first vertical axis coordinates of the graph 300 (marked in the middle of FIG. 5) represents the light intensity. The second vertical axis coordinates of the graph 300 (marked on the right side of FIG. 5) represents the color difference. As shown in FIG. 5, the curve 302 represents the light pattern of the red LED chip 102 in FIG. 1A. The curve 304 represents the light pattern of the green LED chip 104 in FIG. 1A. The curve 306 represents the light pattern of the blue LED chip 106 in FIG. 1A. In some embodiments of FIG. 5, the coordinates on the straight line 310 all correspond to the horizontal 0-degree viewing angle, representing the viewing angle when the user is facing the display. The curve 320 represents the ideal light pattern, that is, the light pattern represented by the curve 320 is symmetrical with respect to the 0-degree viewing angle. The curve 330 is the color difference of the pixel unit 100 in FIG. 1A. In some embodiments, the color difference is affected by the light pattern of the red LED chip 102, the light pattern of the green LED chip 104, and the light pattern of the blue LED chip 106.

In the graph 300 of FIG. 5, the light pattern of the red LED chip 102 (that is, the curve 302), the light pattern of the green LED chip 104 (that is, the curve 304), and the light pattern of the blue LED chip 106 (that is, the curve 306) are asymmetrical with respect to the 0-degree viewing angle (that is, the straight line 310). In detail, the light pattern of the red LED chip 102, the light pattern of the green LED chip 104, and the light pattern of the blue LED chip 106 are deviated to the same side with respect to the horizontal 0-degree viewing angle. For example, in the graph 300, the light pattern of the red LED chip 102 (that is, the curve 302), the light pattern of the green LED chip 104 (that is, the curve 304), and the light pattern of the blue LED chip 106 (that is, the curve 306) are all deviated to the left side (that is, the negative viewing angle) with respect to the horizontal 0-degree viewing angle (that is, the straight line 310). Since the light patterns of the chips of the pixel unit are all deviated to the same side, the difference of the light patterns between the chips of the pixel unit are reduced, and the color difference of the horizontal viewing angle can also be reduced. For example, the color difference within the horizontal +/−45-degree viewing angle falls in the range below 0.01, thus improving the uniformity of color space. That is to say, the user's viewing experience can be effectively improved by increasing the similarity of the light patterns of the chips in the pixel unit to reduce the color difference within the common viewing angle range of ordinary users.

In the graph 300 of FIG. 5, the vertices of the curve 302, the curve 304, and the curve 306 are all located on the left side of the straight line 310. That is, the maximum light intensity of the red LED chip 102, the maximum light intensity of the green LED chip 104, and the maximum light intensity of the blue LED chip 106 are all located on the same side of the horizontal 0-degree viewing angle. In other words, by observing the distribution of the optical density concentration zone of the LED chip when the LED chip is light on, the deviation of the light pattern of the LED chip can be estimated, so that a pixel unit containing three primary color LED chips with the same light pattern can be formed. In the pixel unit 100 in FIG. 1A, FIG. 1B, FIG. 3A, and FIG. 3B, the pixel unit 100′ in FIG. 2A and FIG. 2B, the pixel unit 200 in FIG. 4A, and the pixel unit 210 in FIG. 4B, since the optical density concentration zone of the red LED chip 102 is deviated to the side of the negative electrode of the red LED chip 102, the optical density concentration zone of the green LED chip 104 is deviated to the side of the positive electrode of the green LED chip 104, and the optical density concentration zone of the blue LED chip 106 is deviated to the side of the positive electrode of the blue LED chip 106, the red LED chip 102 and the green LED chip 104 are disposed to be with opposite arrangement of the positions of the positive electrode and negative electrode, so are the red LED chip 102 and the blue LED chip 106. Thus, the embodiments of the present disclosure make the light patterns of the three primary color LED chip in the pixel unit 100, the pixel unit 100′, the pixel unit 200, and the pixel unit 210 to deviated to the same side, to optimize the user experience when using the display component including the pixel unit 100, the pixel unit 100′, the pixel unit 200, or pixel unit 210.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A pixel unit, comprising:
a red light-emitting diode (LED) chip, having an optical density concentration zone and a reference line passing through a geometric center of the top-view shape of the red LED chip, wherein the optical density concentration zone of the red LED chip is deviated to one side of the reference line of the red LED chip;
a green LED chip, having an optical density concentration zone and a reference line passing through a geometric center of the top-view shape of the green LED chip, wherein the optical density concentration zone of the green LED chip is deviated to one side of the reference line of the green LED chip;
a blue LED chip, having an optical density concentration zone and a reference line passing through a geometric center of the top-view shape of the blue LED chip, wherein the optical density concentration zone of the blue LED chip is deviated to one side of the reference line of the blue LED chip;
wherein the reference line of the red LED chip, the reference line of the green LED chip, and the reference line of the blue LED chip are parallel to each other, and the optical density concentration zone of the red LED chip, the optical density concentration zone of the green LED chip, and the optical density concentration zone of the blue LED chip are all deviated to the same side of the respective reference line.

2. The pixel unit as claimed in claim 1, wherein each of the red LED chip, the green LED chip, and the blue LED chip comprises a positive electrode and a negative electrode, the positive electrode and the negative electrode of each of the red LED chip, the green LED chip and the blue LED chip are respectively located on opposite sides of the reference line of the sited chip.

3. The pixel unit as claimed in claim 2, wherein the optical density concentration zone of the red LED chip, the green LED chip, or the blue LED chip is deviated to the side of the positive electrode of the same chip, and the optical density concentration zone of the other among the red LED chip, the green LED chip, and the blue LED chip is deviated to the side of the negative electrode of the same chip.

4. A pixel unit, comprising:
a red LED chip;
a green LED chip; and
a blue LED chip;
wherein each of the red LED chip, the green LED chip, and the blue LED chip has a reference line passing through a geometric center of the top-view shape of the respective chip, and the reference lines of the red LED chip, the green LED chip and the blue LED chip are parallel to each other;
wherein each of the red LED chip, the green LED chip, and the blue LED chip has different average brightness on both sides of the reference line, and the side with higher average brightness of the red LED chip, the green LED chip and the blue LED chip are the same side of the respective reference line.

5. The pixel unit as claimed in claim 4, wherein each of the red LED chip, the green LED chip, and the blue LED chip comprises a positive electrode and a negative electrode, the positive electrode and the negative electrode of each of the red LED chip, the green LED chip and the blue LED chip are respectively located on opposite sides of the reference line of the sited chip.

6. The pixel unit as claimed in claim 5, wherein the side of the red LED chip, the green LED chip, or the blue LED chip with the higher average brightness is the same side as the positive electrode of the same chip, and the side of the others, among the red LED chip, the green LED chip, and the blue LED chip, with the higher average brightness is the same side as the negative electrode of the same chip.

7. A pixel unit, comprising:
a red LED chip;
a green LED chip; and
a blue LED chip;
wherein the respective light patterns of the red LED chip, the green LED chip, and the blue LED chip are asymmetric with respect to the 0-degree viewing angle;
wherein the respective light patterns of the red LED chip, the green LED chip, and the blue LED chip are deviated to the same side with respect to the 0-degree viewing angle.

8. The pixel unit as claimed in claim 7, wherein each of the red LED chip, the green LED chip, and the blue LED chip has a reference line passing through a geometric center of the top-view shape of the chip, and the reference lines of the red LED chip, the green LED chip and the blue LED chip are parallel to each other.

9. The pixel unit as claimed in claim 8, wherein each of the red LED chip, the green LED chip, and the blue LED chip comprises a positive electrode and a negative electrode, and the positive electrode and the negative electrode of each of the red LED chip, the green LED chip and the blue LED chip are respectively located on opposite sides of the reference line of the sited chip.

10. The pixel unit as claimed in claim 9, wherein the side of the red LED chip, the green LED chip, or the blue LED chip where the light pattern is deviated to with respect to the 0-degree viewing angle is the same side as the positive electrode of the same chip, and the side of the others, among the red LED chip, the green LED chip, and the blue LED chip, where the light pattern is deviated to with respect to the 0-degree viewing angle is the same side as the negative electrode of the same chip.
